(19) United States
(12) Patent Application Publication
(10) Pub. No.: US 2012/0329912 A1
(43) Pub. Date: Dec. 27, 2012

(54) FUSED FILLER AND ITS MANUFACTURING METHOD AND USE

(75) Inventors: Cheng-Ping LIU, Chupei City (TW); Jiun-Jie HUANG, Chupei City (TW); Hsien-Te CHEN, Chupei City (TW); Chih-Wei LIAO, Chupei City (TW)

(73) Assignee: TAIWAN UNION TECHNOLOGY CORPORATION, Chupei City (TW)

(21) Appl. No.: 13/227,546

(22) Filed: Sep. 8, 2011

(30) Foreign Application Priority Data
Jun. 27, 2011 (TW) 100122410

(51) Int. Cl. C08K 3/38; H05K 3/46; C04B 14/30

(52) U.S. Cl. 523/445; 106/462; 427/99.4

(57) ABSTRACT

A fused filler and method for manufacturing the same are provided. The fused filler comprises about 50 wt % to about 60 wt % SiO₂, about 10 wt % to about 20 wt % Al₂O₃, about 20 wt % to about 30 wt % B₂O₃ and about 1 wt % to about 5 wt % oxides of IA/IIA metals. The fused filler can be used in a resin composition for preparing prepregs and printed circuit boards.

This application claims priority to Taiwan Patent Application No. 100122410 filed on Jun. 27, 2011.

### CROSS-REFERENCES TO RELATED APPLICATIONS

Not applicable.

### BACKGROUND OF THE INVENTION

1. Field of the Invention

The present invention relates to a fused filler and its manufacturing method and use. Specifically, the present invention relates to a fused filler which can be used as the filler of an epoxy resin composition for preparing a printed circuit board, as well as its manufacturing method and use.

2. Descriptions of the Related Art

Printed circuit boards are circuit substrates that are used for electronic devices to load other electronic components and electrically connect the components to provide a stable circuit working environment. One kind of conventional printed circuit board is a copper clad laminate (CCL), which is primarily composed of resin, reinforcing material and copper foil.

Generally, a printed circuit broad can be prepared by the following steps: immersing a reinforcing material into a resin; drying the immersed reinforcing material to a half-hardened state, i.e. B-stage, to obtain a prepreg; superimposing certain layers of the prepregs and superimposing a metal foil on at least one external surface of the superimposed prepregs to provide a superimposed object; performing a hot-pressing operation onto the superimposed object to C-stage to obtain a metal clad laminate; digging a plurality of holes on the metal clad laminate and plating these holes with a conductive material to form via holes; and finally, etching the metal foil on the surface of the metal clad laminate to form a defined circuit pattern to accomplish the preparation of the printed circuit broad.

In the current industrial processes, filler is usually added into the resin composition to improve the properties of the printed circuit board prepared therefrom, such as hardness, flame resistance, moisture resistance, dielectric constant (Dk), dissipation factor (Df), wear rate of the drill and the like. Conventional fillers include, for example, SiO₂, Al₂O₃, talcum and the like, as disclosed in U.S. Pat. No. 4,798,762 and TW 413659 B which respectively add inorganic materials such as glass microparticles and talcum into the resin composition to improve the dielectric constant and other properties of the printed circuit board. However, glass and talcum always result in a very hard board, and thus an increased wear rate of the drill.

TW 201036820 A1 discloses a fused filler for improving the wear rate of drill. The fused filler comprises 55 wt % to 65 wt % SiO₂, 12 wt % to 22 wt % Al₂O₃, 5 wt % to 15 wt % B₂O₃, 4 wt % to 18 wt % oxide(s) of HA metals (CaO and MgO), and less than 1 wt % oxide(s) of IA metals (K₂O and Na₂O) and Fe₂O₃. However, this case merely focuses on the wear rate of the drill but leaves a considerable room for improvement in the dielectric constant and dissipation factor.

In view of the above, the present invention provides a novel fused filler which may be added into the resin for preparing a printed circuit board. The printed circuit board prepared thereby is provided with a satisfied wear rate of drill as well as an improved dielectric constant and dissipation factor.

### SUMMARY OF THE INVENTION

An object of the present invention is to provide a fused filler, comprising about 50 wt % to about 60 wt % SiO₂, about 10 wt % to about 20 wt % Al₂O₃, about 20 wt % to about 30 wt % B₂O₃ and about 1 wt % to about 5 wt % oxide(s) of IA/IIA metal(s).

Another object of the present invention is to provide a method for manufacturing the above fused filler, comprising:
mixing SiO₂, Al₂O₃, B₂O₃ and oxide(s) of IA/IIA metal(s) with the weight proportions as defined above to provide a first mixture;
melting the first mixture to provide a first slurry;
solidifying the first slurry to provide a fused product; and
grinding the fused product.

Yet another object of the present invention is to provide a resin composition, comprising an epoxy resin, a hardener, and the above fused filler as a filling agent, wherein the hardener is in an amount ranging from about 1 part by weight to about 100 parts by weight per 100 parts by weight of the epoxy resin, the filling agent is in an amount ranging from about 1 part by weight to about 150 parts by weight per 100 parts by weight of the epoxy resin.

Still another object of the present invention is to provide a prepreg obtained by immersing a substrate into the above resin composition and drying the immersed substrate.

Still yet another object of the present invention is to provide a printed circuit board obtained by performing a hot-pressing operation onto a plurality of the above prepregs.

To render the above objects, technical features and advantages of the present invention more apparent, the present invention will be described in detail with reference to some embodiments hereinafter.

### BRIEF DESCRIPTION OF THE DRAWINGS

FIG. 1 shows an optical microscope (OM) imagine of the fused filler A in accordance with the present invention.

### DETAILED DESCRIPTION OF THE INVENTION

The following will describe some embodiments of the present invention in detail. However, without departing from the spirit of the present invention, the present invention may be embodied in various embodiments and should not be limited to the embodiments described in the specification. In addition, unless it is additionally explained, the expressions “a,” “the,” or the like recited in the specification (especially in the claims) should include the singular and the plural forms.

A fused filler generally adopts SiO₂, Al₂O₃, talcum or the like as a matrix; however, such materials have high thermal treatment temperature and unfavorable workability. Therefore, a flux component is usually added to reduce the thermal treatment temperature of the fused filler and to improve the workability of the fused filler. A conventional flux component includes, for example, B₂O₃ and oxides of IA/IIA metals. B₂O₃ is able to reduce the thermal treatment temperature as well as the dielectric constant and dissipation factor of the prepared printed circuit board. However, B₂O₃ also disadvantageously reduces the moisture resistance of the prepared printed circuit board, and increases the board hardness and thus the wear rate of drill. Oxides of IA/IIA metals are able to enhance the moisture resistance of prepared printed circuit board but they also disadvantageously increase the dielectric constant and dissipation factor of the prepared printed circuit board.

In the past, to obtain a print circuit board with proper hardness and moisture resistance, people tend to incorporate less B₂O₃ and more oxides of IIA metals. For example, the filler disclosed in TW 201036820 A1 incorporates at most 15 wt % B₂O₃ and at most 18 wt % oxides of IIA metals. However, such incorporation is disadvantageous to lower the dielectric constant and dissipation factor. The inventors of the present invention found that in a specific proportion, a relatively large amount of B₂O₃ and small amount of oxides of IIA metals can be adopted to effectively reduce the dielectric constant and dissipation factor of the prepared printed circuit board without impairing its moisture resistance. The prepared board is then provided with a proper hardness, which can further reduce the wear of the drill during the drilling operation.

Specifically, the present invention provides a fused filler comprising SiO₂, Al₂O₃, B₂O₃ and oxides of IA/IIA metals. SiO₂ is a matrix of the fused filler of the present invention, which has positive effects for the prepared printed circuit board on the increase of the hardness, solder resistance and adhesion to copper foil, as well as the decrease of the dielectric constant and dissipation factor. However, an excessively high or low amount of SiO₂ will cause disadvantageous effects. For example, an excessively low amount of SiO₂ will make the glass transition temperature (Tg) of the fused filler excessively low and limit the application of the print circuit board using the filler; on the other hand, an excessively high amount of SiO₂ will make the hardness of the prepared board excessively high, and thus increase the wear rate of drill during the drilling operation. Therefore, the amount of SiO₂ in the fused filler of the present invention is about 50 wt % to about 60 wt %. In some embodiments of the present invention, the amount of SiO₂ in the fused filler is about 54 wt %.

Al₂O₃ is a common filler component and features the ability of providing a good flame resistance for the prepared print circuit board. However, an excessively high amount of Al₂O₃ will also make the hardness of the prepared print circuit board excessively high, and thus increase the wear rate of drill during the drilling operation. Therefore, the amount of Al₂O₃ in the fused filler of the present invention is about 10 wt % to about 20 wt %. In some embodiments of the present invention, the amount of Al₂O₃ in the fused filler is about 15 wt %.

In the fused filler of the present invention, the amount of B₂O₃ is about 20 wt % to about 30 wt %, and the total amount of oxides of IA/IIA metals is about 1 wt % to about 5 wt %. If the amounts of these two components (i.e., B₂O₃ and oxides of IA/IIA metals) fall outside of the above ranges, it will adversely affect the properties of the prepared printed circuit board such as the hardness, moisture resistance, dielectric constant, dissipation factor or the like. It should be noted that, in this specification, the term “oxides of IA/HA metals” includes the embodiments of one or more oxides of IA metals, one or more oxides of IIA metals, and any combination of one or more oxides of IA metals and one or more oxides of IIA metals. When a plurality of oxides of IA metals and/or a plurality of oxides of HA metals is used, their total amount should fall within the above suggested range. In some embodiments of the present invention, the amount of B₂O₃ in the fused filler is about 26 wt %, and the oxides of IA/IIA metals, which has a combination of Na₂O, K₂O, CaO and MgO, is accounted for about 4.3 wt %.

There is no special limitation on the shape of the fused filler according to the present invention. However, for convenience (such as dispersing the filler into the resin), the fused filler product is usually grounded into powder, which has a particle size of preferably less than 50 μm and more preferably less than 20 μm. In some embodiments of the present invention, the fused filler is in a form of cylindrical particles. In these embodiments, the cylindrical particles have a diameter of less than 30 μm (preferably less than 20 μm) and a length of less than 150 μm (preferably about 0.5 μm to about 50 μm). Without being restricted by any theory, it is believed that these particles with a specific shape and uniform size distribution can considerably reduce the wear rate of drill during the drilling operation of the prepared print circuit board.

The present invention further provides a method for manufacturing the said fused filler, comprising: mixing SiO₂, Al₂O₃, B₂O₃ and oxides of IA/HA metals with the weight proportion as defined above to provide a first mixture; melting the first mixture to provide a first slurry; solidifying the first slurry to provide a fused product; and grinding the fused product to obtain the fused filler of the invention.

As mentioned above, in some embodiments of the present invention, the fused filler is provided in the form of cylindrical particles to reduce the wear rate of drill during the drilling operation of the prepared printed circuit board. In the solidifying step of these embodiments, the first slurry is solidified through wiredrawing to provide fused filaments with a specific diameter, followed by grinding the fused filaments to a certain length to obtain the desired cylindrical particles.

The present invention also provides a resin composition for manufacturing a printed circuit board, comprising an epoxy resin, a hardener and a filling agent, wherein the filling agent comprises the above fused filler and optionally comprises other conventional fillers, such as SiO₂, glass powders, talcum, Kaolin, pryan, mica and any combination thereof. The amount of the filling agent is about 1 part by weight to about 150 parts by weight, preferably 20 parts by weight to about 40 parts by weight, per 100 parts by weight of the epoxy resin.

In the resin composition of the present invention, there is no special limitation on the epoxy resin; for example, a novolac epoxy resin, a brominated epoxy resin, a phosphor-containing epoxy resin etc. can be used. In some embodiments of the present invention, a brominated epoxy resin (Hexion 1134) or phosphor-containing epoxy resin (CCP 330) is used.

There is no special limitation on the hardener for the resin composition of the present invention, any hardener which can provide the desired hardening effect can be used. For example, in some embodiments of the present invention, the hardener is selected from a group consisting of dicyandiamide (Dicy), 4,4′-diaminodiphenyl sulfone (DDS), and phenol novolac (PN). As for the amount of the hardener, it can be adjusted depending on the user's needs and normally ranges from about 1 part by weight to about 100 parts by weight per 100 parts by weight of the epoxy resin, preferably about 10 parts by weight to about 90 parts by weight per 100 parts by weight of the epoxy resin, but not limited to. Moreover, without being restricted by any theory, more than one kind of hardener may be incorporated into the resin composition of the present invention.

The resin composition of the present invention may optionally include other additives. For example, a hardening promoter selected from a group consisting of 2-methyl-imidazole (2MI), 2-ethyl-4-methyl-imidazole (2E4MI), 2-phenyl-imidazole (2PI) and combinations thereof, but not limited to, may be added to provide an improved hardening effect. The amount of the hardening promoter is generally about 0.01 parts by weight to about 1 part by weight per 100 parts by weight of the epoxy resin. In addition to the above hardening promoter, other conventional additives, such as a dispersing agent (e.g., a silane coupling agent), a flame retardant, a toughening agent etc., may also be optionally added into the resin composition of the present invention, and the additives can be taken alone or in combination.

The resin composition of the present invention may be prepared into varnish form by evenly mixing the epoxy resin, the hardener, the filler agent and the optionally added components through a stirrer. The mixture is then dissolved or dispersed into a solvent such as dimethylformamide (DMF), methyl ethyl ketone (MEK) etc., for subsequent applications. There is no special limitation on the amount of the solvent as long as each component of the resin composition can be evenly mixed. In some embodiments of the present invention, DMF is illustrated as the solvent in an amount of about 60 parts by weight per 100 parts by weight of the epoxy resin.

The present invention further provides a prepreg, which is prepared by immersing a substrate (a reinforcing material) into a varnish from the resin composition of the present invention and drying the substrate under appropriate drying conditions. Suitable conventional reinforcing materials include a glass fiber cloth (glass fiber fabric, glass fiber paper, glass fiber mat, etc.), a kraft paper, a short fiber cotton paper, a nature fiber cloth, an organic fiber cloth, etc. In some embodiments of the present invention, 7628 glass fiber cloths are illustrated as the reinforcing materials, and the reinforcing materials are heated and dried at 180° C. for 2 to 10 minutes (B-stage) to provide prepregs in a half-hardened state.

Moreover, the present invention also provides a printed circuit broad which is manufactured by superimposing a plurality of the above prepregs and superimposing a metal foil (such as copper foil) on at least one external surface of the superimposed prepregs to provide a superimposed object; hot-pressing the object to provide a metal clad laminate; and patterning the clad metal foil.

The present invention will be further illustrated by the embodiments hereinafter, wherein the measuring instruments and methods are respectively as follows:

[H₂O Absorption Test]

The H₂O absorption of the laminate for determining the humidity-resistance of the printed circuit board is tested by the pressure cooker test (PCT), i.e., subjecting the laminate into a pressure container (121° C., 100% R.H. and 2 atm) for 1 hr.

[Solder Floating Endurance Test]

The method for testing the solder floating endurance comprises: immersing a dried laminate in a solder bath at 288° C. for awhile and observing whether there is any defect such as delamination and expansion.

[Peeling Strength Test]

The peeling strength refers to the adhesive force of the clad metal foil to the superimposed prepregs. The adhesive force is generally expressed by the force required for vertically peeling the clad copper foil with a width of one inch (25.4 mm) from the surface of the substrate. The passing standard of a substrate with 1 oz copper foil is 4 lb_{f}/in according to MIL-P-55110E.

[Glass Transition Temperature Test]

The glass transition temperature is measured by a dynamic mechanical analyzer (DMA), wherein the measuring regulations are guided by IPC-TM-650.2.4.25C and 24C testing methods announced by Institute for Interconnecting and Packaging Electronic Circuits (IPC).

[Thermal Decomposition Temperature Test]

The thermal decomposition temperature test is carried out by measuring the mass loss of the sample with a thermogravimetric analyzer (TGA). The temperature where the mass loss is up to 5% is regarded as the thermal decomposition temperature.

[Flammability Test]

The flammability test is carried out according to UL94V (Vertical Burn), which comprises the burning of a laminate, which is held vertically, using a Bunsen burner to obtain its self-ignition and combustion-supporting properties. The result is classified from UL94V-0 (the best) to UL94V-2.

[Dielectric Constant (Dk) and Dissipation Factor (Df) Measurement]

Dk and Df are measured according to ASTM D150 under an operating frequency of 1 GHz.

[Barcol Hardness Test]

Barcol hardness is determined by Rockwell E value of the printed circuit board measured by a hardness tester (Barber Colman Inc., model: GYZJ934-1).

### EXAMPLES

### The Preparation of the Fused Filler

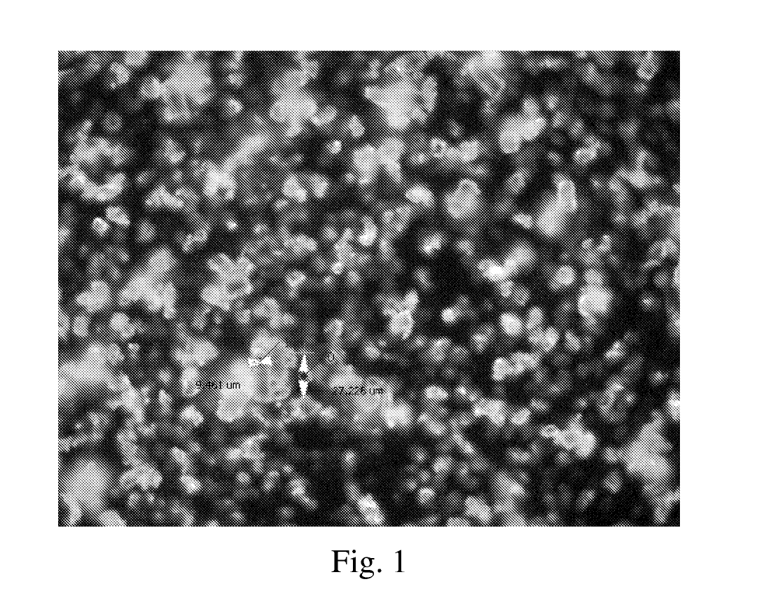

SiO₂, Al₂O₃, B₂O₃, CaO, MgO, K₂O, and Na₂O were evenly mixed with the proportion as shown in Table 1 to form a mixture. The mixture was then melted to form a melt which was then solidified through wiredrawing to form fused filaments with a diameter of about 10 μm. Then, the resultant filaments were milled by zirconia balls and sieved to provide a cylindrical filler with a cylindrical length of about 30 nm, and thus accomplishing the preparation of fused filler A. FIG. 1 shows the OM image of fused filler A, which shows that the particles of fused filler A are cylindrical in form.

TABLE 1

| component | wt % |
|---|---|
| SiO₂ | about 54 |
| Al₂O₃ | about 15 |
| B₂O₃ | about 26 |
| CaO | about 1 |
| MgO | about 3 |
| Na₂O and K₂O | about 0.3 |

### The Preparation of the Resin Composition

### Example 1

A brominated epoxy resin (Hexion 1134), DDS (AULT Inc.), 2MI, a silane coupling agent (Z-6040) and fused filler A were mixed with the proportion shown in Table 2 and stirred at room temperature for 60 minutes by using a stirrer; 60 parts by weight of DMF was then added thereinto. After stirring the resultant mixture at room temperature for 120 minutes, resin composition 1 was obtained.

### Example 2

The preparation procedures of Example 1 were repeated for resin composition 2, except that the brominated epoxy resin was replaced by 100 parts by weight of phosphor-containing epoxy resin (CCP 330), as shown in Table 2.

### Example 3

The preparation procedures of Example 1 were repeated for resin composition 3, except that DDS was replaced by 30 parts by weight of PN (Kolon 2004), as shown in Table 2.

### Example 4

The preparation procedures of Example 1 were repeated to prepare resin composition 4, except that the mixture of 20 parts by weight of fused filler A and 10 parts by weight of talcum powder (Yan-Tai company, LT102) was used as the filler agent, as shown in Table 2.

### Comparative Example 1

The preparation procedures of Example 1 were repeated to prepare comparative resin composition 1, except that fused filler A was replaced by 30 parts by weight of E-glass filler, as shown in Table 3. The amount of B₂O₃ in the E-glass filler is less than 10 wt %, and the total amount of oxides of IA and IIA metals is more than 20 wt %.

### Comparative Example 2

The preparation procedures of Example 1 were repeated to prepare comparative resin composition 2, except that fused filler A was replaced by 30 parts by weight of talcum powder (Yan-Tai company, LT102), as shown in Table 3.

### Comparative Example 3

The preparation procedures of Example 1 were repeated to prepare comparative resin composition 3, except that fused filler A was replaced by 30 parts by weight of SiO₂ (SIBELCO company, 925), as shown in Table 3.

[The Preparation of the Printed Circuit Board]

The printed circuit broads were prepared by using the resin compositions of Examples 1 to 4 and Comparative Examples 1 to 3, respectively. In detail, the resin composition of one of Examples 1 to 4 and Comparative Examples 1 to 3 was coated on a plurality of 7628 glass fiber cloths (resin/glass fiber cloth: 43%) by a roll coater. The coated 7628 glass fiber cloths were then placed in a dryer and dried at 180° C. for 2 to 10 minutes to prepare prepregs in a half-hardened state. Four pieces of the prepregs were superimposed and two copper foils (1 oz) were respectively superimposed on the two external surfaces of the superimposed prepregs to provide a superimposed object. A hot-pressing operation was performed onto the superimposed object to provide a metal clad laminate, wherein the hot-pressing conditions were as follows: raising the temperature to 180° C. with a raising rate of 2.0° C./min, and hot-pressing for 60 minutes under the full pressure of 15 kg/cm² (the initial pressure was 8 kg/cm²) at 180° C. Finally, the clad copper foils were patterned to form a circuit pattern to obtain the desired printed circuit broad.

The H₂O absorption, solder floating endurance, peeling strength, glass transition temperature (Tg), thermal decomposition temperature, flammability, dielectric constant, dissipation factor and Barcol hardness of the printed circuit boards were tested and the results were shown in Table 2 (Examples 1 to 4) and Table 3 (Example 1 and Comparative Examples 1 to 3).

TABLE 2

| | | Ex. 1 | Ex. 2 | Ex. 3 | Ex. 4 |
|---|---|---|---|---|---|
| epoxy resin | brominated | 100 | — | 100 | 100 |
| | epoxy resin | | | | |
| | DOPO | — | 100 | — | — |
| hardener | DDS | 20 | 20 | — | 20 |
| | PN | — | — | 30 | — |
| hardening | 2MI | 0.5 | 0.5 | 0.5 | 0.5 |
| promoter | | | | | |
| dispersing | slicane | 0.3 | 0.3 | 0.3 | 0.3 |
| agent | coupling | | | | |
| | agent | | | | |
| filler agent | fused filler A | 30 | 30 | 30 | 20 |
| | E-glass filler | — | — | — | — |
| | talcum | — | — | — | 10 |
| | powder | | | | |
| | SiO₂ | — | — | — | — |
| solvent | DMF | 60 | 60 | 60 | 60 |

The hot-pressing condition: raising the temperature to 180° C. with a
raising rate of 2.0° C./min, and hot-pressing for 60 minutes under a full
pressure of 15 kg/cm² (the initial pressure is 8 kg/cm²) under 180° C.

| | | | | | |
|---|---|---|---|---|---|
| H₂O absorption | % | 0.41 | 0.52 | 0.44 | 0.40 |
| solder floating | min | >10 | >10 | >10 | >10 |
| endurance | | | | | |
| peeling strength | lb_{f}/in | 9.56 | 8.97 | 9.01 | 8.75 |
| Tg | ° C. | 175 | 170 | 172 | 174 |
| thermal | ° C. | 341 | 367 | 344 | 342 |
| decomposition | | | | | |
| temperature | | | | | |
| UL94 | level | V0 | V0 | V0 | V0 |
| dielectric | GHz | 4.2 | 4.5 | 4.4 | 4.6 |
| constant | | | | | |
| dissipation | GHz | 0.014 | 0.013 | 0.015 | 0.018 |
| factor | | | | | |
| Barcol hardness | Rockwell E | 66 | 63 | 63 | 61 |
| | vale | | | | |

TABLE 3

| | | | Com. | Com. | Com. |
|---|---|---|---|---|---|
| | | Ex. 1 | Ex. 1 | Ex. 2 | Ex. 3 |
| epoxy resin | brominated | 100 | 100 | 100 | 100 |
| | epoxy resin | | | | |
| | DOPO | — | — | — | — |
| hardener | DDS | 20 | 20 | 20 | 20 |
| | PN | — | — | — | — |
| hardening | 2MI | 0.5 | 0.5 | 0.5 | 0.5 |
| promoter | | | | | |
| dispersing | slicane | 0.3 | 0.3 | 0.3 | 0.3 |
| agent | coupling | | | | |
| | agent | | | | |
| filler agent | fused filler A | 30 | — | — | — |
| | E-glass filler | — | 30 | — | — |
| | talcum | — | — | 30 | — |
| | powder | | | | |
| | SiO₂ | — | — | — | 30 |
| solvent | DMF | 60 | 60 | 60 | 60 |

The hot-pressing condition: raising the temperature to 180° C. with a
raising rate of 2.0° C./min, and hot-pressing for 60 minutes under a full
pressure of 15 kg/cm² (the initial pressure is 8 kg/cm²) under 180° C.

| | | | | | |
|---|---|---|---|---|---|
| H₂O absorption | % | 0.41 | 0.41 | 0.42 | 0.47 |
| solder floating | min | >10 | >10 | >10 | >10 |
| endurance | | | | | |
| peeling strength | lb_{f}/in | 9.56 | 9.42 | 7.54 | 8.51 |
| Tg | ° C. | 175 | 176 | 172 | 172 |
| thermal | ° C. | 341 | 341 | 342 | 357 |
| decomposition | | | | | |
| temperature | | | | | |
| UL94 | level | V0 | V0 | V0 | V0 |
| dielectric | GHz | 4.2 | 4.5 | 4.8 | 4.4 |
| constant | | | | | |
| dissipation | GHz | 0.014 | 0.017 | 0.021 | 0.019 |
| factor | | | | | |
| Barcol hardness | Rockwell E | 66 | 70 | 56 | 86 |
| | vale | | | | |

As shown in Table 2 for the cases of using different epoxy resins and hardeners (Examples 1 to 3), the fused filler of the present invention impart good dielectric constants, good dissipation factors and proper hardness to the prepared printed circuit boards, and can be optionally combined with other fillers (Example 4) to provide a printed circuit board with different properties. Furthermore, as shown in Table 3, compared to the commercial E-glass filler (Comparative Example 1), the fused filler of the present invention imparts a lower dielectric constant and dissipation factor as well as a more proper hardness of the prepared printed circuit board; in comparison to the talcum powder filler (Comparative Example 2), the fused filler of the present invention can greatly improve the dissipation factor of the prepared printed circuit board as well as the peeling strength, dielectric constant, etc.; and in comparison to the SiO₂ filler (Comparative Example 3), the fused filler of the present invention can greatly improve the hardness of the prepared printed circuit board, and also effectively improve the dielectric constant, the dissipation factor and the peel strength of the prepared printed circuit board.

The above disclosure is related to the detailed technical contents and inventive features thereof. People skilled in this field may proceed with a variety of modifications and replacements based on the disclosures and suggestions of the invention as described without departing from the characteristics thereof. Nevertheless, although such modifications and replacements are not fully disclosed in the above descriptions, they have substantially been covered in the following claims as appended.

What is claimed is:

1. A fused filler, comprising about 50 wt % to about 60 wt % SiO₂, about 10 wt % to about 20 wt % Al₂O₃, about 20 wt % to about 30 wt % B₂O₃ and about 1 wt % to about 5 wt % oxide(s) of IA/IIA metal(s).

2. The fused filler of claim 1, which is in a form of cylindrical particles.

3. The fused filler of claim 2, wherein the cylindrical particles have a diameter of less than 30 μm and a length of less than 150 μm.

4. The fused filler of claim 3, wherein the cylindrical particles have a length of about 0.5 μm to about 50 μm.

5. The fused filler of claim 1, which is prepared by the following steps:
mixing SiO₂, Al₂O₃, B₂O₃ and oxide(s) of IA/IIA metal(s) with the weight proportions as defined in claim 1 to provide a first mixture;
melting the first mixture to provide a first slurry;
solidifying the first slurry to provide a fused product; and
grinding the fused product.

6. The fused filler of claim 5, wherein in the solidifying step, the first slurry is solidified by wiredrawing to provide fused filaments.

7. A resin composition, comprising:
an epoxy resin;
a hardener; and
a filling agent, comprising the fused filler of claim 1, wherein the hardener is in an amount ranging from about 1 part by weight to about 100 parts by weight per 100 parts by weight of the epoxy resin, the filling agent is in an amount ranging from about 1 part by weight to about 150 parts by weight per 100 parts by weight of the epoxy resin.

8. The resin composition of claim 7, wherein the amount of the filling agent is about 20 parts by weight to about 40 parts by weight per 100 parts by weight of the epoxy resin.

9. The resin composition of claim 7, wherein the filling agent further comprises a component selected from a group consisting of SiO₂, glass powder, talcum, kaolin, pryan, mica and any combinations thereof.

10. The resin composition of claim 7, which further comprises a hardening promoter, a dispersant, a toughening agent, a flame retardant or a combination thereof.

11. A prepreg, which is prepared by immersing a substrate into the resin composition of claim 7 and drying the immersed substrate.

12. The prepreg of claim 11, which is used for preparing a printed circuit board.
